(19) United States
(12) Patent Application Publication
(10) Pub. No.: US 2021/0247453 A1
(43) Pub. Date: Aug. 12, 2021

(54) METHODS, SYSTEMS, AND DEVICES FOR CHARGING ADVANCED SEALED LEAD ACID BATTERIES

(71) Applicant: EnerSys Delaware Inc., Reading, PA (US)

(72) Inventors: Robert PAYNE, Greensboro, NC (US); Matthew PAYNE, Coed Eva (GB); Wayne COLDRICK, Bettws (GB)

(21) Appl. No.: 17/167,190

(22) Filed: Feb. 4, 2021

Related U.S. Application Data
(60) Provisional application No. 62/971,475, filed on Feb. 7, 2020.

(51) Int. Cl. G01R 31/387; H02J 7/00

(52) U.S. Cl. CPC G01R 31/387; H02J 7/0048

(57) ABSTRACT

Some battery chemistries, such as “advanced carbon” battery chemistries may have improved battery health if maintained with longer intervals between “full” recharge. Accordingly, methods, systems, and devices are provided in which a state of charge of a battery is determined; the state of charge of the battery is compared to at least one threshold; a charge profile is selected from a plurality of charge profiles based on a result of the comparison of the state of charge of the battery to the at least one threshold; and a charger configured to charge the battery is modified based on the selected charge profile.

### CROSS-REFERENCE TO RELATED APPLICATION

The present application claims priority to U.S. Provisional Application 62/971,475, filed on Feb. 7, 2020, with the United States Patent and Trademark Office, the entire contents of which are incorporated by reference herein for all purposes.

### TECHNICAL FIELD

The present disclosure relates to batteries, and in particular, to methods, systems, and devices for charging batteries, and in particular to methods, systems, and devices for charging sealed lead acid batteries.

### BACKGROUND

Batteries have become increasingly important, with a variety of industrial, commercial, and consumer applications. Of particular interest are power applications involving “deep discharge” duty cycles, such as motive power applications. The term “deep discharge” refers to the extent to which a battery is discharged during service before being recharged. By way of counter example, a shallow discharge application is one such as starting an automobile engine wherein the extent of discharge for each use is relatively small compared to the total battery capacity. Moreover, the discharge in such shallow discharge cases is followed soon after by recharging. Over a large number of repeated cycles very little of the battery capacity is used prior to recharging.

Conversely, deep discharge duty cycles are characterized by drawing a substantial majority of the battery capacity before the battery is recharged. Some motive power applications that require deep cycle capability include Class 1 electric rider trucks, Class 2 electric narrow aisle trucks and Class 3 electric hand trucks. Desirably, batteries installed in these types of vehicles must deliver a number of discharges during a year that may number in the hundreds. The cycle life of batteries used in these applications typically can range from 500-2000 total cycles, and as such a battery may last a number of years before it needs to be replaced.

Interest and research in batteries has resulted in a variety of battery chemistries, with differing benefits and drawbacks. For example, “flooded” lead-acid batteries tend to be more economical, but may require periodic maintenance such as replenishment of an electrolyte, which can spill. “Sealed” lead-acid batteries may require periodic maintenance via charging or “overcharging” of the battery to prevent stratification. Stratification is the result of acid in the battery electrolyte separating from the water, resulting in non-homogenous concentrations of each in different parts of the battery. Without such periodic maintenance, sealed lead-acid batteries may have reduced capacity over time resulting from the liberation of acid during charging. Alternative lead-acid batteries may use a gelled electrolyte, which cannot spill and avoid the acid liberation problem, but have their own drawbacks in that the internal resistance may be higher, limiting the ability of such batteries to deliver high currents.

Other types of batteries include lithium-ion or lithium-ion polymer batteries, nickel-cadmium, nickel-metal hydride, and others. The benefits and drawbacks of such battery types are known to those in the art and need not be discussed here.

### SUMMARY

Aspects of the present disclosure are directed to lead-carbon batteries, another type of battery chemistry in which carbon is added to the cathode (the negative plate). Such chemistry may reduce the growth of irreversible lead sulfate on the negative plate; this may result in increased performance and battery lifespan. Such a battery may be referred to herein as an “advanced carbon” battery, or a battery having advanced carbon. As recognized by the present application, among the potential advantages of advanced carbon batteries is an understanding that battery health may be maintained with longer intervals between “full” recharge.

Aspects of the present disclosure provide a method. The method may include: determining a state of charge of a battery; comparing the state of charge of the battery to at least one threshold; selecting a charge profile from a plurality of charge profiles based on a result of the comparison of the state of charge of the battery to the at least one threshold; and modifying a charger configured to charge the battery based on the selected charge profile.

In some aspects, the method may include charging the battery using the modified charger. The charge profile may indicate a threshold of a property of the battery at which a charging of the battery is to be terminated.

In some aspects, comparing the state of charge of the battery may include comparing the state of charge of the battery to both a first threshold and a second (lower) threshold. In some aspects, comparing the state of charge (SoC) of the battery to at least one threshold may include determining that the SoC of the battery is greater than the first threshold, and selecting the charge profile may include selecting a high SoC charge profile. In some aspects, the high SoC charge profile may be configured to modify the charger such that charging of the battery terminates prior to the battery reaching 100% SoC. In some aspects, comparing the state of charge (SoC) of the battery to at least one threshold may include determining that the SoC of the battery is less than the first threshold and greater than the second threshold, and selecting the charge profile may include selecting a medium SoC charge profile. In some aspects, comparing the state of charge (SoC) of the battery to at least one threshold may include determining that the SoC of the battery is less than the first threshold and less than the second threshold, and selecting the charge profile may include selecting a low SoC charge profile. The low SoC charge profile may be configured to modify the charger such that a full recharge of the battery is performed.

In some aspects, at least one charge profile of the plurality of charge profiles is configured to modify the charger such that charging of the battery terminates prior to the battery reaching 100% SoC.

In some aspects, the SoC of the battery is estimated based on an open-circuit voltage (OCV) of the battery. In some aspects, the SoC of the battery is determined based on data received from a component within a battery monitoring system.

Aspects of the present disclosure also provide systems and devices in accordance with the inventive concepts of the present disclosure. For example, some aspects of the present disclosure provide a system comprising a battery monitor in communication with a charger, where the charger is configured to determine a state of charge of a battery; compare the state of charge of the battery to at least one threshold; select a charge profile from a plurality of charge profiles based on a result of the comparison of the state of charge of the battery to the at least one threshold; and charge the battery based on the selected charge profile. Some aspects of the present disclosure provide a charger comprising a processor and memory, where the memory stores computer-readable instructions that, when executed by the processor, cause the processor to: determine a state of charge of a battery; compare the state of charge of the battery to at least one threshold; select a charge profile from a plurality of charge profiles based on a result of the comparison of the state of charge of the battery to the at least one threshold; and charge the battery based on the selected charge profile.

Aspects of the present disclosure provide a method. The method may include determining whether a full charge of a battery is required; selecting a low state of charge (SoC) charge profile from a plurality of charge profiles based on a determining that the full charge of the battery is required; and modifying a charger configured to charge the battery based on the selected low SoC charge profile.

Some aspects of the present disclosure provide a system that includes a battery monitor in communication with a charger. The charger may be configured to determine whether a full charge of a battery is required; select a low state of charge (SoC) charge profile from a plurality of charge profiles based on a determination that the full charge of the battery is required; and charge the battery based on the selected low SoC charge profile. Some aspects of the present disclosure provide a charger that includes a processor and memory, the memory storing machine-readable instructions that, when executed by the processor, cause the processor to: determine whether a full charge of a battery is required; select a low state of charge (SoC) charge profile from a plurality of charge profiles based on a determination that the full charge of the battery is required; and charge the battery based on the selected low SoC charge profile.

The present disclosure is not limited to those aspects explicitly recited above, and other aspects will be apparent to those of skill in the art upon reviewing the description of the inventive concepts disclosed herein.

### BRIEF DESCRIPTION OF THE DRAWINGS

The accompanying drawings, which are incorporated in and constitute a part of the specification, illustrate embodiments of the inventive concepts and, together with the description, serve to explain principles of the inventive concepts.

FIG. 1 is a flowchart of an example battery charging method according to some embodiments of the present inventive concepts.

FIG. 2 is a flowchart of an example battery charging method according to some embodiments of the present inventive concepts.

FIG. 3 is a schematic block diagram illustrating an example battery monitoring system according to some embodiments of the present inventive concepts.

FIG. 4 is a schematic block diagram of various components of a computing device, which may be used in the implementation of one or more of the devices of the battery monitoring system of FIG. 3, as well as other devices discussed herein.

### DETAILED DESCRIPTION

In addition to the battery chemistries discussed in the Background section, a more recently developed alternative to classic lead acid batteries is a lead-carbon battery, in which carbon is added to the cathode (the negative plate). Such chemistry may reduce the growth of irreversible lead sulfate on the negative plate; this may result in increased performance and battery lifespan. Such a battery may be referred to herein as an “advanced carbon” battery, or a battery having advanced carbon.

The present disclosure is based on the recognition that included among the potential advantages of advanced carbon batteries is that battery health may be maintained with longer intervals between “full” recharge. The present disclosure is based on a recognition that these longer intervals may be leveraged to potentially prolong the lifespan of a battery even further.

Typically, a battery may be charged using a charging profile in which a constant current (CC) is first applied to the battery until the charging voltage reaches a predetermined set point. When the voltage of the battery reaches the predetermined set point, the charger may switch to applying a constant voltage (CV) to the battery until the battery reaches a predetermined termination condition, typically chosen to correspond to 100% charge return. After this, a lower float voltage, lower constant current, or other voltage may be applied to account for charge inefficiency, to ensure weaker cells are returned to a full state of charge (SoC), to maintain the battery in a “fully charged” state, and to replace charge lost due to self-discharge or parasitic loads.

Aspects of the present disclosure provide for using an initial SoC of a battery at initialization of a charging operation to select from a plurality of charging profiles that determine characteristics of how the battery is to be charged during the charging operation. At least one of the charging profiles is designed to give the battery less charge during the charging operation than would be needed to restore the battery to a 100% SoC.

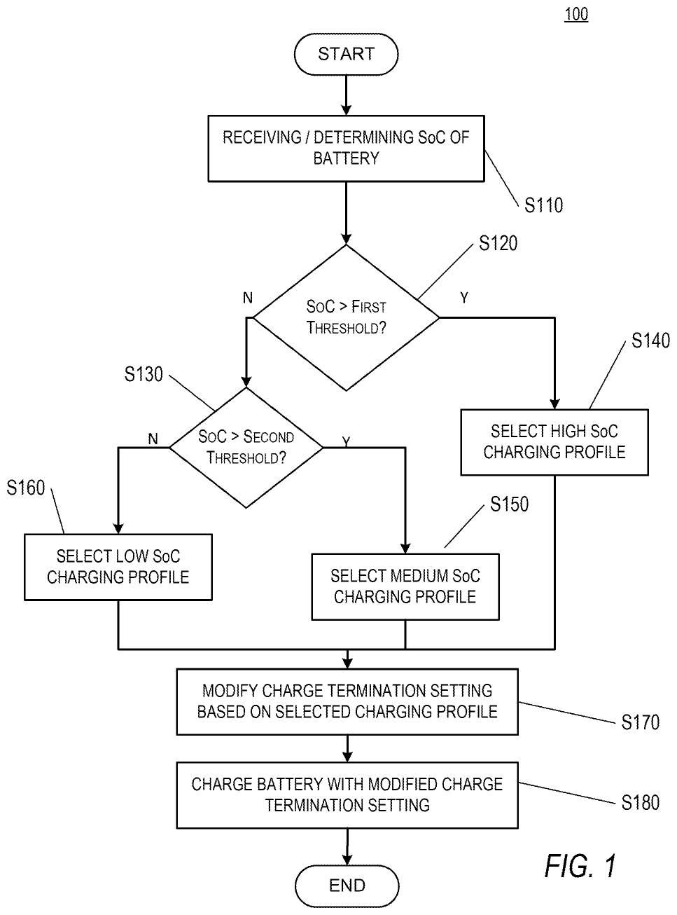

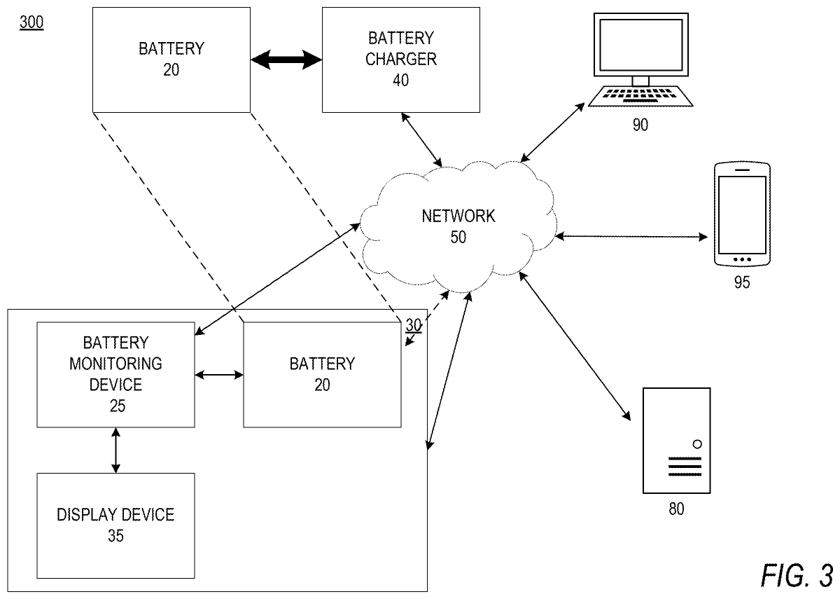

FIG. 1 is a flowchart of an example battery charging method 100 according to some embodiments of the present inventive concepts. In operation S110, an initial state of charge (SoC) of a battery to be charged (e.g., battery 20 of FIG. 3) may be received or determined at a charging device (e.g., charger 40 of FIG. 3) to which the battery to be charged is connected or installed.

In some embodiments, a SoC of the battery may be communicated to the charger from a component within a battery management system or battery monitoring system, an example of which is provided in FIG. 3. In some embodiments, and based on the recognition that SoC is difficult to measure directly, the SoC of the battery may be estimated. For example, one technique is simple coulomb counting, which measures battery charge and discharge current over time. Another technique is using the open-circuit voltage (OCV) of the battery when it is coupled to the charge, as the OCV of the battery may be a sufficiently reliable indicator of an approximate depth of discharge (DoD) of the battery, and accordingly an indicator of an approximate SoC of the battery.

In operation S120 of FIG. 1, the SoC of the battery is compared with a first threshold, which may be a predetermined threshold. If the SoC of the battery is greater than the first threshold (or, in some embodiments, greater than or equal to the first threshold) (“Y” branch from operation S120), then the method may proceed to operation S140. Otherwise, (“N” branch from operation S120), the method may proceed to operation S130.

In operation S130, the SoC of the battery is compared with a second threshold, which may be a predetermined threshold. If the SoC of the battery is greater than the second threshold (or, in some embodiments, greater than or equal to the second threshold) (“Y” branch from operation S130), then the method may proceed to operation S150. Otherwise, (“N” branch from operation S130), the method may proceed to operation S160. The first threshold may be greater than the second threshold. For example, the first threshold may be a SoC of the battery of greater than 80%, and the second threshold may be a SoC of the battery of greater than 50%, although the present disclosure is not limited to this sole example.

In operation S140, the SoC has been determined to be greater than the first threshold. Accordingly, the charger may consider the battery to have a “high” SoC (relative to the first and second thresholds). Thus, in operation S140, a high SoC charging profile may be selected. The high SoC charging profile may have characteristics or properties that result in intentionally less charge given to the battery than is required to bring the battery to 100% SoC. For example, a charge termination setting or trigger point (e.g., a point at which a charging voltage is removed from the battery) may be included in high SoC charging profile, which may result in the charging voltage being removed from the battery before it is fully charged.

In operation S150, the SoC has been determined to be less than the first threshold and greater than the second threshold. Accordingly, the charger may consider the battery to have a “medium” SoC (relative to the first and second thresholds). Thus, in operation S150, a medium SoC charging profile may be selected. The medium SoC charging profile may have characteristics or properties that result in an amount charge given to the battery than is approximately equal to the charge deficit. For example, a charge termination setting or trigger point (e.g., a point at which a charging voltage is removed from the battery) may be included in medium SoC charging profile, which may result in the charging voltage being removed from the battery when it is approximately fully charged, or just under.

In operation S160, the SoC has been determined to be less than the first threshold and less than the second threshold. Accordingly, the charger may consider the battery to have a “low” SoC (relative to the first and second thresholds). Thus, in operation S160, a low SoC charging profile may be selected. The low SoC charging profile may have characteristics or properties that result in an amount charge given to the battery than is approximately equal to that required to bring the battery to 100% SoC, plus an additional fixed time period at constant voltage (CV) and/or constant current (CC). For example, a charge termination setting or trigger point (e.g., a point at which a charging voltage is removed from the battery) may be included in low SoC charging profile, which may result in the charging voltage being removed from the battery after a fixed time beyond its full charge condition.

The low SoC scenario may reflect that a more complete recharge may be needed to bring the battery back to full state of charge and balance the cells.

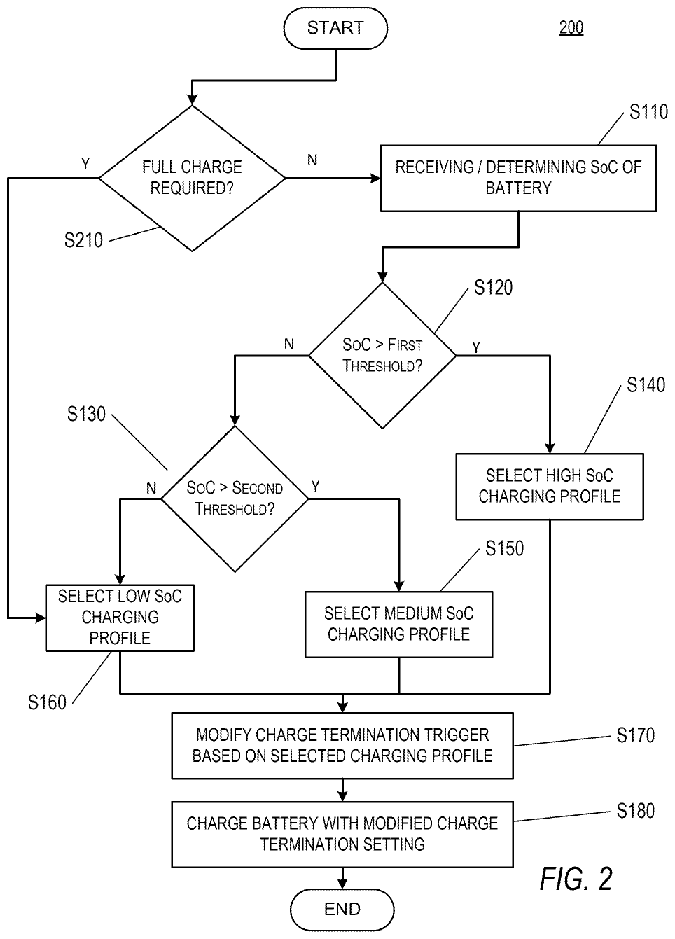

FIG. 2 is a flowchart of an example battery charging method according to some embodiments of the present inventive concepts. FIG. 2 is similar to FIG. 1, and like reference numbers refer to like elements therein. However, in some embodiments, it is recognized that the full recharge provided from selecting the low SoC charge profile can also be initiated by the battery management or battery monitoring system when a certain usage threshold has been breached. Thus, in operation S210, the charger (or battery monitoring system) may determine whether a full charge is required. If so (“Y” branch from operation S210), then the low SoC charging profile is selected. Otherwise (“N” branch from operation S210), the charger or battery monitoring system may proceed as in FIG. 1. In other words, the initial state of charge of the battery may be overridden by the battery monitoring system. In some embodiments, the full charge could be triggered by time since the last full charge, or by cumulative power output by the charger since the last full charge.

In both FIG. 1 and FIG. 2, properties or characteristics of the charger may be modified based on the selected charging profile in operation S170. An example is the charge termination trigger previously discussed, although the present disclosure is not limited thereto. The battery may be charged using the modified properties or characteristics in operation S180. In some embodiments, once a charging profile is selected, the selected charging profile is used until the charge termination setting or trigger point is reached.

FIG. 3 illustrates an example battery monitoring system 300 in accordance with aspects of the present disclosure. In FIG. 3, a battery 20 may monitored by one or more components, including for example battery monitoring device 25.

The phrase “battery monitoring” as used herein may include measuring values of properties of a battery at a point in time and/or over a period of time. “Battery monitoring” may also include estimating values of battery properties at past and/or present points in time, relative to a time when the estimation is performed. For example, a property may be estimated where the property is difficult, time-consuming, or energy-consuming to measure directly. First and second values measured at first and second points in time, respectively, may be used to estimate a third value at a third point in time occurring in between the first and second points in time. “Battery monitoring” may also include predicting future values of battery properties at a point in time in the future relative to when the prediction is made. Such predicted future values may be based on one or more measured and/or estimated values of properties of the battery, at points in time at and/or before when the prediction is made. Example properties that may be measured, estimated, and/or predicted may include current (e.g., current flowing to the battery, current flowing from the battery), voltage (e.g., open-circuit voltage, voltage applied to load), battery temperature, battery state of charge, time remaining to charge, time remaining to discharge, and so on. Measured, estimated, and/or predicted battery properties may be based on other measured, estimated, and/or predicted properties of the battery. Other data or information available within the battery monitoring system 300 may also be used to measure, estimate, and/or predict battery properties, such as models of complex battery properties, stored history of battery usage data, and so on.

The battery 20 may be of any type compatible with the present disclosure, with an example being a lead-acid battery that includes carbon and so on. The battery 20 may have one or more sensors proximate thereto (not shown in FIG. 3), which may be configured to detect one or more characteristics or properties of the battery 20, such as current or voltage. For example, a current sensor may be used to sense current flowing to the battery 20 and/or current flowing from the battery 20; a voltage sensor may be used to sense a voltage of the battery 20 (such as under load or OCV). Such sensors may be integrated into the battery 20 or present elsewhere within the battery monitoring system 300, such as within the battery monitoring device 25.

As illustrated in FIG. 3, the battery 20 may be used by a vehicle 30 in operation thereof. For example, the battery 20 may be mounted in the vehicle 30. The battery monitoring device 25 may be located relatively proximate to the battery 20 (e.g., within the vehicle 30) or may be relatively remote from the battery (e.g., not within the vehicle 30). In some embodiments, the battery 20 may be detachable or disconnectable from the vehicle 30. The battery 20 may be configured to be temporarily attachable to a charger 40 for charging thereof. The charger 40 may be of any type compatible with the present disclosure and may be configured to provide a charging current to batteries of one or more types.

The battery monitoring device 25 may be electrically and/or communicatively coupled to the battery 20 and configured to receive measurements from the sensors of battery 20 and/or the sensors of the battery monitoring device 25 and communicate the measurements to one or more recipients. Estimations and/or predictions of battery properties based on the measurements may also be communicated. Examples of recipients may include a user of the vehicle 30 in which the battery 20 is installed. Data may be communicated (e.g., graphically, tabularly, and/or numerically) to the user of the vehicle 30 via an user interface, such as a display device 35 mounted in a dashboard of the vehicle 30 or otherwise visible to the user during operation of the vehicle 30. Other examples of recipient may be computing devices 90 and 95, which may communicate with the battery monitoring device 25 over a network 50, and which may be smartphones, tablets, desktop computers, laptop computers, thin clients, mainframes, servers, and so on. The computing devices 90 and 95 may be running software configured to receive the data and/or other values from the battery 20 and/or the battery monitoring device 25 and perform one or more actions based thereon. As an example of such actions, the computing device 90 may be configured to receive data and/or other values from the battery 20 and/or the battery monitoring device 25, determine a notification (e.g., a notification of a SOC of the battery 20, a notification of a remaining run time of the battery 20) should be sent to the computing device 95, and cause transmission of the notification to the computing device 95, for example via the network 50. In some embodiments, the battery monitoring device 25 may be integrated with the battery 20. In some embodiments, the battery monitoring device 25 may be integrated with the vehicle 30 and/or the charger 40.

In some embodiments, sensed values of properties, estimations of values of properties, and/or predictions of values of properties may be stored in a database at database server 80. The database server 80 may be a part of any of the computing devices of FIG. 3, the battery monitoring device 25, and/or a separate device as illustrated.

In some embodiments, functionality described herein as being performed by the battery monitoring device 25 may be performed additionally or alternatively by one or more of the computing devices 90, 95 in the battery monitoring system 300 of FIG. 3, For example, proximate to the battery 20 may be sensors, which may sense properties of the battery 20 and communicate the sensed properties over the network 50 to one or more of the computing devices 90, 95, as indicated by the dashed arrow between the battery 20 and the network 50. The computing devices 90, 95 may analyze the communicated sensed properties and perform one or more estimations and/or predictions. In some embodiments, all or part of the battery monitoring device 25 may overlap with one or more of the devices of the battery monitoring system 300 of FIG. 3, including the computing devices 90, 95 or the database server 80.

The battery 20, the battery monitoring device 25, the charger 40, and/or the computing devices 90, 95 may include a display device for displaying measurements, estimations, and/or predictions (e.g., graphically, tabularly, and/or numerically). In some embodiments, the battery 20, the battery monitoring device 25, the charger 40, and/or the computing devices 90, 95 may include input devices configured to accept user input, such as an initial state of charge of the battery 20, desired type of output/display, user settings (e.g., temperature values provided in Celsius or Fahrenheit) and so on.

The network 50 may include a local network, a wireless, coaxial, fiber, or hybrid fiber/coaxial distribution system, a Wi-Fi or Bluetooth network, or any other desired network. The network 50 may be made up of one or more subnetworks, each of which may include interconnected communication links of various types, such as coaxial cables, optical fibers, wireless links, and the like. The network 50 and/or the subnetworks thereof may include, for example, networks of Internet devices, telephone networks, cellular telephone networks, fiber optic networks, local wireless networks (e.g., WiMAX, Bluetooth), satellite networks, and any other desired network, and each device of FIG. 3 may include the corresponding circuitry needed to communicate over the network 50, and to other devices on the network. Although the devices of the battery monitoring system 300 of FIG. 3 are illustrated as communicating over a common network 50, in some embodiments various point-to-point or device-to-device networks or communication links may be used in addition to or alternatively from the common network 50 for example to communicate data between a first device (e.g., the battery monitoring device 25) and a second device (e.g., the computing device 95). Furthermore, although each component of the illustrated battery monitory system 300 is shown as directly connected to the network 50 in FIG. 3, in some embodiments devices may be coupled to the network via other devices, gateways, and so on.

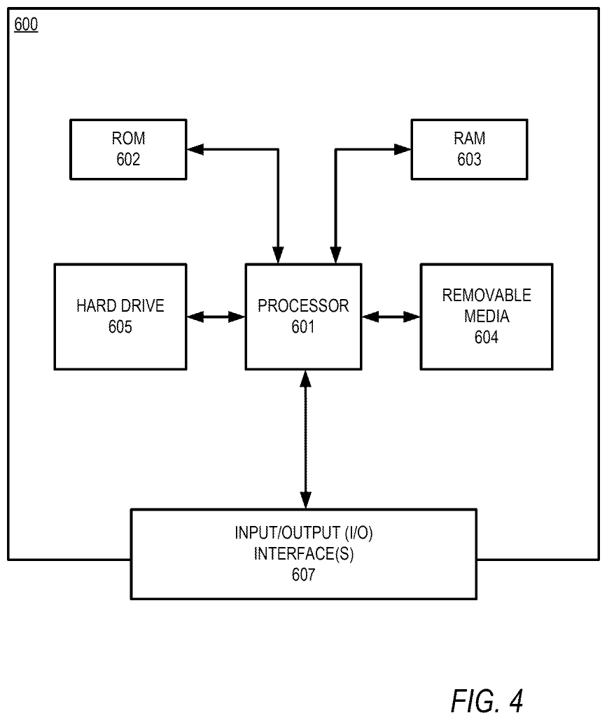

FIG. 4 illustrates various components of a computing device 600 which may be used to implement one or more of the devices herein, including the battery monitoring device 25, the database 80, and/or the computing devices 90, 95 of FIG. 3. FIG. 4 illustrates hardware elements that can be used in implementing any of the various computing devices discussed herein. In some aspects, general hardware elements may be used to implement the various devices discussed herein, and those general hardware elements may be specially programmed with instructions that execute the algorithms discussed herein. In special aspects, hardware of a special and non-general design may be employed (e.g., ASIC or the like). Various algorithms and components provided herein may be implemented in hardware, software, firmware, or a combination of the same.

A computing device 600 may include one or more processors 601, which may execute instructions of a computer program to perform any of the features described herein. The instructions may be stored in any type of computer-readable medium or memory, to configure the operation of the processor 601. For example, instructions may be stored in a read-only memory (ROM) 602, random access memory (RAM) 603, removable media 604, such as a Universal Serial Bus (USB) drive, compact disk (CD) or digital versatile disk (DVD), floppy disk drive, or any other desired electronic storage medium. Instructions may also be stored in an attached (or internal) hard drive 605. The computing device 600 may be configured to provide output to one or more output devices (not shown) such as printers, monitors, display devices, and so on, and receive inputs, including user inputs, via input devices (not shown), such as a remote control, keyboard, mouse, touch screen, microphone, or the like. The computing device 200 may also include input/output interfaces 607 which may include circuits and/or devices configured to enable the computing device 600 to communicate with external input and/or output devices (e.g., the battery 20, network devices of the network 50) on a unidirectional or bidirectional basis. The components illustrated in FIG. 4 (e.g., processor 601, ROM storage 602) may be implemented using basic computing devices and components, and the same or similar basic components may be used to implement any of the other computing devices and components described herein. For example, the various components herein may be implemented using computing devices having components such as a processor executing computer-executable instructions stored on a computer-readable medium, as illustrated in FIG. 4.

The various inventive concepts provide several distinctive advantages. First, the inventive concepts provided herein provide a comprehensive algorithm for providing an improved lifespan of a battery having advanced carbon. The inventors have recognized that prior systems did not provide such comprehensiveness, if indeed the characteristics of a battery having advanced carbon were even considered at all.

Second, the present inventive concepts provide for selection of battery charging trigger points for terminating the charge, which may be based upon a delta of the current level being accepted by the battery over a given time (Di/Dt). These trigger points may provide for prolonged lifespan of the battery.

The inventive concepts provided by the present disclosure have been be described above with reference to the accompanying drawings and examples, in which examples of embodiments of the inventive concepts are shown. The inventive concepts provided herein may be embodied in many different forms than those explicitly disclosed herein, and the present disclosure should not be construed as limited to the embodiments set forth herein. Rather, the examples of embodiments disclosed herein are provided so that this disclosure will be thorough and complete, and will fully convey the scope of the inventive concepts to those skilled in the art. Like numbers refer to like elements throughout.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

Some of the inventive concepts are described herein with reference to block diagrams and/or flowchart illustrations of methods, apparatus (systems) and/or computer program products, according to embodiments of the inventive concepts. It is understood that one or more blocks of the block diagrams and/or flowchart illustrations, and combinations of blocks in the block diagrams and/or flowchart illustrations, can be implemented by computer program instructions. These computer program instructions may be provided to a processor of a general purpose computer, special purpose computer, and/or other programmable data processing apparatus to produce a machine, such that the instructions, which execute via the processor of the computer and/or other programmable data processing apparatus, create means for implementing the functions/acts specified in the block diagrams and/or flowchart block or blocks.

These computer program instructions may also be stored in a computer-readable memory that can direct a computer or other programmable data processing apparatus to function in a particular manner, such that the instructions stored in the computer-readable memory produce an article of manufacture including instructions which implement the function/act specified in the block diagrams and/or flowchart block or blocks.

The computer program instructions may also be loaded onto a computer or other programmable data processing apparatus to cause a series of operational steps to be performed on the computer or other programmable apparatus to produce a computer-implemented process such that the instructions which execute on the computer or other programmable apparatus provide steps for implementing the functions/acts specified in the block diagrams and/or flowchart block or blocks.

Accordingly, the inventive concepts may be embodied in hardware and/or in software (including firmware, resident software, micro-code, etc.). Furthermore, embodiments of the present inventive concepts may take the form of a computer program product on a computer-usable or computer-readable non-transient storage medium having computer-usable or computer-readable program code embodied in the medium for use by or in connection with an instruction execution system.

The computer-usable or computer-readable medium may be, for example but not limited to, an electronic, optical, electromagnetic, infrared, or semiconductor system, apparatus, or device. More specific examples (a non-exhaustive list) of the computer-readable medium would include the following: an electrical connection having one or more wires, a portable computer diskette, a random access memory (RAM), a read-only memory (ROM), an erasable programmable read-only memory (EPROM or Flash memory such as an SD card), an optical fiber, and a portable compact disc read-only memory (CD-ROM).

The terms first, second, etc. may be used herein to describe various elements, but these elements should not be limited by these terms. These terms are only used to distinguish one element from another. For example, a first element could be termed a second element, and, similarly, a second element could be termed a first element, without departing from the scope of the present inventive concepts. As used herein, the term “and/or” includes any and all combinations of one or more of the associated listed items. As used herein, the singular forms “a”, “an” and “the” are intended to include the plural forms as well, unless the context clearly indicates otherwise. It should be further understood that the terms “comprises,” “comprising,” “includes,” and/or “including” when used herein, specify the presence of stated features, operations, elements, and/or components, but do not preclude the presence or addition of one or more other features, operations, elements, components, and/or groups thereof.

When an element is referred to as being “on” another element, it can be directly on the other element or intervening elements may also be present. In contrast, when an element is referred to as being “directly on” another element, there are no intervening elements present. When an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

The terminology used herein is for the purpose of describing particular embodiments only and is not intended to be limiting of the present disclosure.

Aspects and elements of all of the embodiments disclosed above can be combined in any way and/or combination with aspects or elements of other embodiments to provide a plurality of additional embodiments. Although a few exemplary embodiments of the inventive concepts have been described, those skilled in the art will readily appreciate that many modifications are possible in the exemplary embodiments without materially departing from the novel teachings and advantages of the inventive concepts provided herein. Accordingly, all such modifications are intended to be included within the scope of the present application as defined in the claims.

What is claimed is:

1. A method comprising:
determining a state of charge of a battery;
comparing the state of charge of the battery to at least one threshold;
selecting a charge profile from a plurality of charge profiles based on a result of the comparing of the state of charge of the battery to the at least one threshold; and
modifying a charger configured to charge the battery based on the selected charge profile.

2. The method of claim 1, further comprising charging the battery using the modified charger.

3. The method of claim 2, wherein the charge profile indicates a threshold of a property of the battery at which a charging of the battery is to be terminated.

4. The method of claim 1, wherein the at least one threshold comprises a first threshold and a second threshold that is less than the first threshold.

5. The method of claim 4, wherein comparing the state of charge of the battery to at least one threshold comprises determining that the state of charge of the battery is greater than the first threshold, and wherein selecting the charge profile comprises selecting a high state-of-charge charge profile.

6. The method of claim 5, wherein the high state-of-charge charge profile is configured to modify the charger such that charging of the battery terminates prior to the battery reaching 100% state of charge.

7. The method of claim 5, wherein comparing the state of charge of the battery to at least one threshold comprises determining that the state of charge of the battery is less than the first threshold and greater than the second threshold, and wherein selecting the charge profile comprises selecting a medium state-of-charge charge profile.

8. The method of claim 7, wherein comparing the state of charge of the battery to at least one threshold comprises determining that the state of charge of the battery is less than the first threshold and less than the second threshold, and wherein selecting the charge profile comprises selecting a low state-of-charge charge profile.

9. The method of claim 8, wherein the low state-of-charge charge profile is configured to modify the charger such that a full recharge of the battery is performed.

10. The method of claim 1, wherein at least one charge profile of the plurality of charge profiles is configured to modify the charger such that charging of the battery terminates prior to the battery reaching 100% state of charge.

11. The method of claim 1, wherein the state of charge of the battery is estimated based on an open-circuit voltage (OCV) of the battery.

12. The method of claim 1, wherein the state of charge of the battery is determined based on data received from a component within a battery monitoring system.

13. A system comprising a battery monitor in communication with a charger, wherein the charger is configured to:
determine a state of charge of a battery;
compare the state of charge of the battery to at least one threshold;
select a charge profile from a plurality of charge profiles based on a result of the comparing of the state of charge of the battery to the at least one threshold; and
charge the battery according to the selected charge profile.

14. The system of claim 13, wherein the at least one threshold comprises a first threshold and a second threshold that is less than the first threshold.

15. The system of claim 14, wherein the charger is configured to compare the state of charge of the battery to the first threshold, and wherein the charger is configured to select the charge profile comprises a high state-of-charge charge profile in response to the state of charge of the battery being greater than the first threshold.

16. The system of claim 15, wherein the charger is configured to compare the state of charge of the battery to the second threshold, and wherein the charger is configured to select a medium state-of-charge charge profile in response to the state of charge of the battery being less than the first threshold and greater than the second threshold.

17. The system of claim 16, wherein the charger is configured to select a low state-of-charge charge profile in response to the state of charge of the battery being less than the first threshold and less than the second threshold.

18. A method comprising:
determining whether a full charge of a battery is required;
selecting a low state-of-charge charge profile from a plurality of charge profiles based on a determining that the full charge of the battery is required; and
modifying a charger configured to charge the battery based on the selected low state-of-charge charge profile.

19. The method of claim 18, wherein the low state-of-charge charge profile is configured to modify the charger such that a full recharge of the battery is performed.

20. The method of claim 18, wherein at least one charge profile of the plurality of charge profiles is configured to modify the charger such that charging of the battery terminates prior to the battery reaching 100% state of charge.
